(19) United States
(12) Patent Application Publication
(10) Pub. No.: US 2002/0057560 A1
(43) Pub. Date: May 16, 2002

(54) Shielding case and electronic device having the same

(75) Inventor: Masanobu Okada, Sagamihara-shi (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 10/042,833

(22) Filed: Jan. 8, 2002

Related U.S. Application Data
(62) Division of application No. 09/627,021, filed on Jul. 27, 2000.

(30) Foreign Application Priority Data
Aug. 2, 1999 (JP) 11-218433

(51) Int. Cl. B23P 19/00; H05K 9/00

(52) U.S. Cl. 361/818; 29/762

(57) ABSTRACT

A shielding case can be easily removed for reworking. Insertion openings and cutouts individually continuing to the insertion openings are provided. To remove the shielding case fixed by soldering from a substrate, first, for example, edges of nippers are inserted into a pair of the insertion openings; then, the leg section is cut away by the nippers. The above cutting-away processing is sequentially performed for all the leg sections. Subsequently, a cover section is removed, solders fixing the individual leg sections are sequentially heated and melted one by one, and the leg sections are serially pulled out from the substrate. Thus, the shield case can be removed from the substrate.

### BACKGROUND OF THE INVENTION

1. Field of the Invention

The present invention relates to a shielding case that serves as an electromagnetic shield for electronic components.

The invention also relates to an electronic device having the aforementioned shielding case.

2. Description of the Related Art

FIG. 5 is a schematic view of an example shielding case 1 mounted on a circuit substrate 4. The shielding case 1 shown in FIG. 5 has a cover section 2 and multiple leg sections 3 (four leg sections 3a, 3b, 3c, and 3d). The shielding case 1 serves as an electromagnetic shield for, for example, RF electronic components (not shown) mounted on the circuit substrate 4. The cover section 2 is formed in the shape of a box opening on the side the circuit substrate 4. Each of the leg sections 3 protrudes from a substrate-side-opening end of the cover section 2 toward the circuit substrate 4.

As shown in FIG. 6, the shielding case 1 is formed as the aforementioned box shown in FIG. 5 by bending a metal plate (such as a BeCu plate, nickel-silver plate, a tin plate, or a corrugated sheet) along dotted lines.

Through-holes 6 (6a, 6b, 6c, and 6d) corresponding to the individual leg sections 3 are formed in an area surrounding electronic components that are to be electromagnetically shielded. The individual leg sections 3 of the shielding case 1 are inserted in the corresponding through-holes 6, and are soldered and fixed on the reverse face of the circuit substrate 4. Thus, the shielding case 1 is mounted onto the circuit substrate 4.

After the shielding case 1 is mounted, there are cases where quality-control testing is performed to determine whether circuits on the circuit substrate 4 properly operate according to design specifications. As a result of the testing, if a circuit mounted on the circuit substrate 4 is not working sufficiently because of a defect found in an electronic component electromagnetically shielded in the shielding case 1, component-replacement process or some correction operations (which is referred to reworking as follows) are performed. The reworking is performed such that the shielding case 1 is removed, and the defective electronic component is replaced with a new suitable component.

In the reworking, the shielding case 1 is removed in the following steps. First, all solders fixing the leg sections 3 of the shielding case 1 are simultaneously heated and are melted. Then, in the state where all the solders are melted, the cover section 2 is lifted in the direction in which the cover section 2 will be separated from the circuit substrate 4. In this state, the individual leg sections 3 are pulled out through the through-holes 6 provided on the circuit substrate 4. In this way, the shielding case 1 can be removed from the circuit substrate 4.

However, since the shielding case 1 is removed in the above procedure, problems as described below may arise.

When the shielding case 1 is removed, multiple scattered solders must be simultaneously heated. However, a ready-made tool for simultaneously heating scattered solders is not available. Therefore, a special device capable of simultaneously heating multiple solders must be prepared to perform the reworking.

In addition, while the solders are heated, heat is gradually conducted to the cover section 2 via the leg sections 3; that is, heat is conducted to the entire shielding case 1. Therefore, it takes time for the temperature of the solders to reach a level at which the solders melt after heating of the solders is started. This decreases operation efficiency.

As described above, while the solders are being heated, heat is conducted from the solders to the cover section 2 via the leg sections 3. Thus, since heating of the solders results in heating of the entire shielding case 1, the temperature of the shielding case 1 increases to substantially the same degree as that at which the solders melt. The high temperature transferred from the shielding case 1 occasionally damages peripheral components and circuits of the shielding case 1.

### SUMMARY OF THE INVENTION

The present invention has been made to solve the problems described above.

Accordingly, an object of the invention is to provide a shielding case that can be easily removed from a circuit substrate without causing damage to electronic components in the shielding case and peripheral components and circuits thereof.

Another object of the present invention is to provide an electronic device that has the shielding case.

To these ends, according to one aspect of the present invention, there is provided a shielding case for serving as an electromagnetic shield, which has a cover section for covering electronic components mounted on a substrate; and a plurality of leg sections for attaching, each of which protrudes from the cover section toward the substrate and is inserted in through-holes provided on the substrate; and a plurality of tool-insertion openings provided on the cover section for use in cutting the leg sections away from the cover section.

The shielding case may further have a plurality of cutouts on the cover section, each of which is extended from an edge of an opening on the substrate-side to each of the tool-insertion openings.

According to another aspect of the present invention, there is provided a shielding case for serving as an electromagnetic shield, which has a cover section for covering electronic components mounted on a substrate; a plurality of leg sections for attaching, each of which protrudes from the cover section toward the substrate and is inserted in through-holes provided on the substrate; and a plurality of tool-insertion openings which is provided serially on the cover section along cutting lines for separating the leg sections to which the plurality of tool-insertion openings correspond via tool-cutting portions, thereby allowing the cover section to be separated for each of the leg sections.

Further, the cover section is defined as a box-like shape in which the cover section having an opening at the substrate side, and the tool-insertion openings may be formed on the top portion of the cover section, which opposes the substrate.

According to yet another aspect of the present invention, there is provided an electronic device that has the shielding case as described above.

As described above, since the shielding case has the tool-insertion openings, the shielding case is removed from the substrate in the following steps in reworking.

First, edges of a cutting-out tool, such as nippers, are inserted into the tool-insertion openings; the leg sections of the shielding case are thereby cut away from the cover section. Then, the cover section which is cut away from the leg sections without any fixed portion to the substrate is removed from the substrate.

Subsequently, solders fixing the individual leg sections to the substrate are sequentially heated and melted one by one by using, for example, a soldering iron. Then the leg sections are sequentially pulled out by each. In this way, the shielding case can be removed from the substrate.

As described above, since the tool-insertion openings are formed on the shielding case, various advantages can be provided as follows.

Each leg section can be easily cut away from the cover section so as to be broken down into individual pieces of leg section before the solders are heated. Thus, the shielding case is disassembled by cutting the leg section from the cover section. Also, since the individual leg sections are disassembled into each piece of the leg sections, the solder of each leg section can be sequentially heated and melted. Thereby, since solders which are located apart at plural positions need not be simultaneously heated, a conventional device which was used for this particular purpose is not required.

By using an ordinary tool, such as nippers, the individual leg sections can be easily separated from the cover section of the shielding case. Also, the cover section can be cut and divided into each piece of the leg sections along the cutting-guide lines for separating the corresponding leg sections. In this way, after the cover section is cut and divided into each piece of the leg sections, solders fixing the individual leg sections are sequentially heated and melted one by one, and each pieces of the leg sections is pulled out from the substrate through the through-hole. Therefore, the shielding case can be completely removed from the substrate.

Thus, since the tool-insertion holes are provided in the shielding case, the operation to separate the shielding case can be performed easily and rapidly, and reworking efficiency can thereby be improved.

In addition, each of the solders is heated and melted in the state where each of the leg sections is cut away, and the size of the leg section to which the solder is applied is considerably small compared to the overall shielding case. Therefore, compared to the conventional case, the period from the time when heating is started up to the time when the temperature reaches a level at which the solder melts is significantly reduced. This significantly reduces the time required to remove the shielding case.

A very small quantity of heat is dissipated via the leg sections while the solders are being heated. This prevents possible damages due to heating to electronic components packaged in the shielding case and peripheral components and circuits when the shielding case is removed.

Moreover, the cutouts which is extended from the edge of the opening on the substrate side to the tool-insertion opening are provided. Also, the tool-insertion openings are provided on the top portion of the cover section. In either of these cases, the cover section can be cut away even more easily for the individual leg sections. This further improves the efficiency of processing for removing the shielding case.

In addition, for the electronic device that has the characteristic shielding case according to the invention, reworking efficiency can be improved. Also, in the reworking, possible damage due to heating of components and circuits can be prevented. Therefore, reduction in yield can be prevented.

Furthermore, even in the case where the shielding case of the present invention is used for miniaturized electronic devices, removal processing therefor, which was conventionally difficult, can now be easily implemented. Therefore, reworking efficiency for miniaturized electronic devices can be significantly improved.

### BRIEF DESCRIPTION OF THE DRAWINGS

FIG. 1 is an explanatory view of a shielding case according to a first embodiment of the present invention;

FIG. 2 is an explanatory view of a shielding case according to a second embodiment of the present invention;

FIG. 3 is an explanatory view of a shielding case according to a third embodiment of the present invention;

FIGS. 4A and 4B are explanatory views of shielding cases according to other embodiments of the present invention;

FIG. 5 is an explanatory view of an example conventional shielding case with a circuit substrate; and

FIG. 6 is an explanatory view of an example metal plate used for the shielding case according to the present invention.

### DESCRIPTION OF THE PREFERRED EMBODIMENTS

Hereinbelow, referring to the accompanying drawings, embodiments of the present invention are described. First of all, a first embodiment is described.

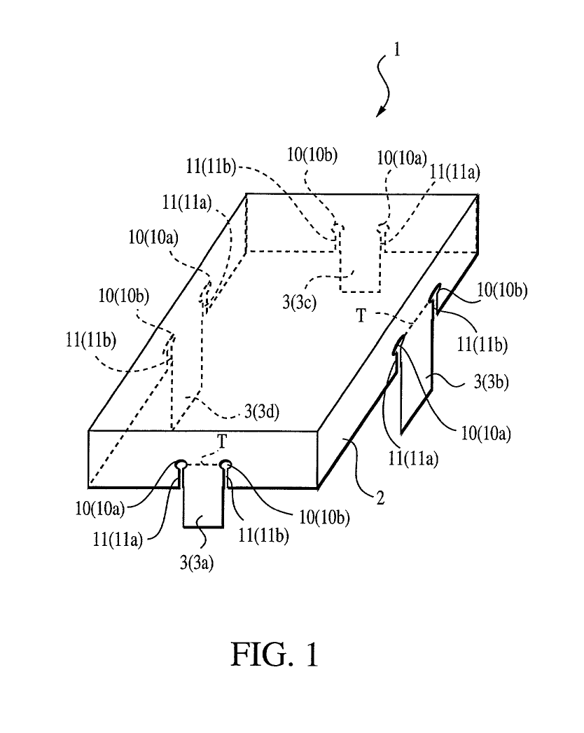

FIG. 1 is a view of a characteristic shielding case 1 according to the first embodiment of the present invention.

The shielding case 1 of the first embodiment has characteristics differing from those of the conventional example described in the Related Art. The first embodiment is characterized in that, as shown in FIG. 1, leg sections 3 (which may also be specifically referred to with reference symbols 3a to 3d) are formed that can be easily removed from a cover section 2. Other portions in the first embodiment are substantially the same as those of the conventional example. For the portions that are substantially the same as those of the conventional example, the same reference symbols as used for the conventional example are used, and detailed descriptions are omitted.

As shown in FIG. 1, the shielding case 1 of the first embodiment has a plurality of tool-insertion openings 10 (which may also be specifically referred to with reference symbols 10a to 10b) and cutouts 11 (which may also be specifically referred to with reference symbols 11a to 11b) on peripheral side faces of the cover section 2 of the shielding case 1. Each of the tool-insertion openings 10 allows insertion of an edge of a cutting tool, such as nippers. In the first embodiment, a pair of the tool-insertion openings 10a and 10b is formed in the vicinity of each of the leg sections 3.

Each of the cutouts 11 is formed by cutting the cover section 2 from the edge of the opening provided on the substrate side of the cover section 2 up to each of the tool-insertion openings 10. In the example shown in FIG. 1, the direction in which the each of the cutouts 11 is formed is substantially parallel to the direction in which each of the leg sections 3 protrudes. Also, a pair of the cutouts 11a and 11b is provided so as to sandwich a base section of each of the leg sections 3.

In the embodiment shown in FIG. 1, there may be a concern that the electromagnetic-shielding effect will be reduced by the tool-insertion openings 10 and the cutouts 11. However, the shape and size of the openings 10 and cutouts 11 are predetermined in view of wavelengths of electromagnetic waves generated by electronic components packaged in the shielding case 1 and by peripheral circuits so as to be effective for electromagnetic shielding. The size and shape of the opening sections 10 and the cutouts 11 can be determined from results of experiments or operations.

Thus, in the first embodiment, the tool-insertion openings 10 and the cutouts 11 are formed in a size and shape that are predetermined in view of wavelengths of electromagnetic waves generated inside and outside of the shielding case 1 so that reduction in the electromagnetic-shielding effect can be securely prevented. For example, the tool-insertion openings 10 and the cutouts 11 are shaped to have a long-direction length and a width-direction length that are different from each other. In this case, a strong effect for preventing reduction in the electromagnetic shielding can be obtained.

As described above, although the first embodiment has the tool-insertion openings 10 and the cutouts 11, the electromagnetic-shielding effect of the shielding case 1 is not reduced.

As in the case of the conventional example, the shielding case 1 of the first embodiment thus configured is attached on a circuit substrate 4 provided in an electronic device (for example, a communication device such as a portable telephone or a PC card).

When reworking is performed, the shielding case 1 of the first embodiment can be removed from the circuit substrate 4 according to a procedure that makes use of the tool-insertion openings 10 and cutouts 11 as described below.

First of all, for example, edges of a cutting tool such as nippers are inserted in the pair of tool-insertion openings 10a to 10b. Then, the base section of the leg section 3 is held between the tool edges and is cut away from the cover section 2 along a dotted line T shown in FIG. 1. In this manner, all the leg sections 3 are cut away one by one. After all the leg sections 3 are cut away, the cover section 2 is no longer fixed to the substrate and is removed from the circuit substrate 4. After the cover section 2 is removed, each of the leg sections 3 are located apart, and it remains soldered to the circuit substrate 4.

Subsequently, a solder fixing each of the individual leg sections 3 is heated and melted using, for example, a soldering iron, and is pulled out and removed through a through-hole 6 by using, for example, tweezers.

In this way, the cover section 2 and the multiple leg sections 3 of the shielding case 1 are removed from the circuit substrate 4, and the shielding case 1 can thereby be completely removed from the circuit substrate 4.

According to the first embodiment, since the tool-insertion openings 10 and the cutouts 11 are provided on the cover section 2, the shielding case 1 can be easily removed from the circuit substrate 4. In the first embodiment, processing to cut away the leg sections 3 from the cover section 2, which is one of the steps to separate the shielding case 1 from the substrate, can be performed easily and rapidly by using the ordinary cutting tool, such as nippers. In addition, similarly to the above, processing to pull out each piece of the leg sections 3 from the through-holes 6 of the circuit substrate 4 can also be performed easily and rapidly by heating and melting each of the solders fixing the respective leg sections 3 after the leg sections 3 are cut away from the cover section and divided into individual pieces of leg section.

In addition, since the solders fixing the leg sections 3 are heated and melted one by one, the ordinary heating tool, such as the soldering iron, can be used to heat and melt the solders. This avoids the necessity of using any conventional devices which was used for this particular purpose to heat and melt the solders simultaneously which are located apart at plural positions.

In addition, as described above, the solders fixing the individual leg sections 3 are heated and melted after the leg sections 3 are cut away and divided into each piece of the leg sections 3. Since each of the leg sections 3 is considerably small compared to the overall shielding case 1, the period from the time when heating is started up to the time when the temperature reaches a level at which the solder is being melted is significantly reduced as is compared to the conventional case. This significantly reduces the time required to remove the shielding case 1.

As described above, according to the first embodiment, the present configuration is provided, and the shielding case 1 is removed using the characteristic procedure that can be implemented because of the characteristic configuration. Thereby, the shielding case 1 can be removed easily and rapidly from the circuit substrate 4, and in addition, efficiency in the reworking can be greatly improved.

In addition, according to the first embodiment, when the shielding case 1 is removed, the solders fixing the individual leg sections 3 are heated after the leg sections are disassembled into each of the leg sections 3. Since each of the leg sections 3 is relatively small compared to the overall shielding case 1, as described above, only a small quantity of heat is dissipated from the solder via the leg section 3 when the solder is heated. This prevents the problem of causing damage due to heating of components packaged in the shielding case 1 and peripheral components and circuits.

In addition, as described above, reworking for the circuit substrate 4 can be efficiently performed, and possible damage due to heating in the reworking can be avoided. Therefore, in reworking of electronic devices, each having the characteristic shielding case 1 according to the first embodiment, problems in the yield can be prevented.

Particularly, recent electronic devices are increasingly required to be miniaturized, and therefore, to be suitable for high-frequency applications. In this situation, use of the characteristic shielding case 1 of the first embodiment for electronic devices is highly advantageous to achieve improvement in the reworking efficiency and yield.

Hereinbelow, a description will be given of a second embodiment of the present invention.

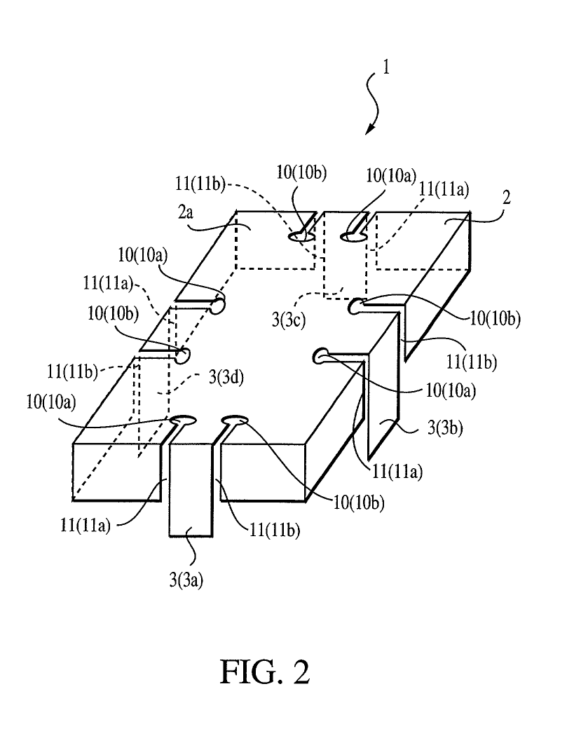

The second embodiment is shown in FIG. 2, insertion openings 10 are provided on the top portion 2a of a cover section 2, which is arranged opposite to a substrate. For the portions that are substantially the same as those of the first embodiment, the same reference symbols as were used for the first embodiment are used, and detailed descriptions are omitted.

As described above, the second embodiment has substantially the same configuration as that of the first embodiment. Therefore, in the second embodiment, by using substantially the same characteristic procedural steps as those used in the first embodiment, a shielding case 1 can be removed from a circuit substrate 4. Also, advantages similar to those produced by the first embodiment can be provided in the second embodiment.

In the second embodiment, the tool-insertion openings 10 are provided on the top portion 2a of the cover section 2. this allows an edge of a cutting tool, such as nippers, to be easily inserted into each of the tool-insertion openings 10 from top surface. In particular, the insertion openings 10 in this embodiment are even more effective in a case where components on the circuit substrate 4 are arranged in high density. In a circuit substrate 4 that has a high density of components, it is difficult to insert the edges of the cutting tool (such as nippers) into the insertion openings 10 from the side surfaces of the cover section 2 as described in the first embodiment. However, as shown in FIG. 2, since the insertion openings 10 are provided on the top portion 2a of the cover section 2, the cutting tool can be easily inserted and cut from the top surface of the cover section 2, thereby greatly improving the efficiency of the processing to remove the shielding case 1.

Hereinbelow, a description will be given of a third embodiment.

Similarly to the above, for substantially the same portions of the third embodiment as those of the described first and second embodiments, the same reference symbols which were used therein are used, and descriptions will be omitted.

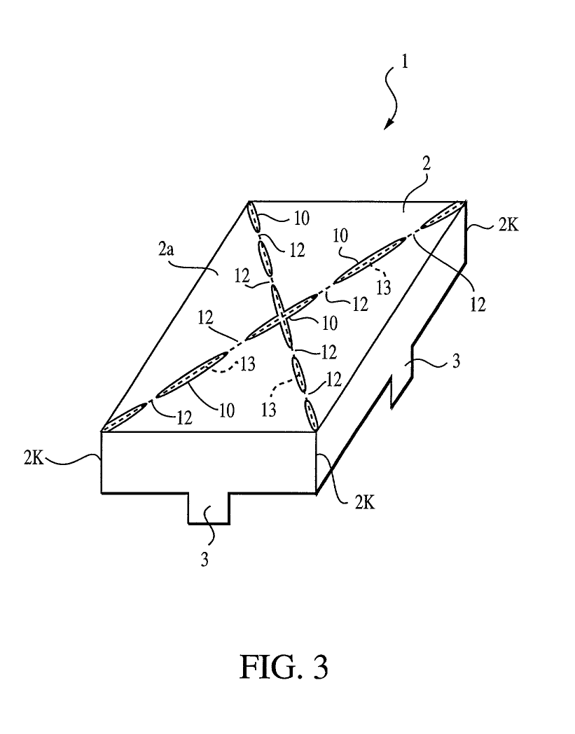

As shown in FIG. 3, in the third embodiment, multiple insertion openings 10 are continuously provided on the top portion 2a of a cover section 2 along cutting guide lines 13 that are shown for cutting and separating leg sections 3 corresponding to the tool-insertion openings 10 via tool-cutting sections 12. As a matter of course, in the third embodiment, similarly to the individual embodiments described above, the insertion openings 10 are formed in a shape and size that are effective for preventing reduction in electromagnetic-shielding effects.

FIG. 6 shows a metal plate 5 used to form the shielding case 1. The shielding case 1 is formed by bending the metal plate 5. As can be seen therefrom, edges in each of the corner sections 2k of the cover section 2 are not connected or not joined to each other.

The shielding case 1 thus formed can also be removed from the circuit substrate 4 according to procedural steps similar to those described each of the embodiments described above. For example, first, edges of a cutting tool are inserted in the adjacent insertion openings 10. Then, the tool-cutting section 12 of the cover section 2 is cut along 4 the cutting guide line 13. This step is serially performed for all the tool-cutting sections 12.

In the example shown in FIG. 3, by performing the above cutting operations, the cover section 2 is cut into quarters and is separated for each piece of the leg sections 3. Subsequently, solders fixing the individual leg sections 3 are serially heated and melted, and the individual leg sections 3 are pulled out one by one from the circuit substrate 4 through through-holes 6. Then, the shielding case 1 can be removed from the circuit substrate 4.

According to the third embodiment, the multiple insertion openings 10 are arranged along the cutting lines 13 that are shown for use in cutting and separating the respective leg sections 3. Therefore, the shielding case 1 can be removed from the circuit substrate 4 in procedural steps similar to those in the individual embodiments described above. Accordingly, the above allows the provision of good advantages similar to those in the individual embodiments described above.

The present invention is not restricted to the described first to third embodiments, but may be embodied differently. For example, in the described first to third embodiments, the shielding case 1 has four leg sections 3. However, the number of the leg sections 3 may be either less than four or may be five or more. Thus, the number of the leg sections 3 is not restricted and may be arranged as required.

Also, in the first to third embodiments, the shielding case 1 is formed of the metal plate. However, it may be formed of, for example, a metal net that has electromagnetic-shielding characteristics.

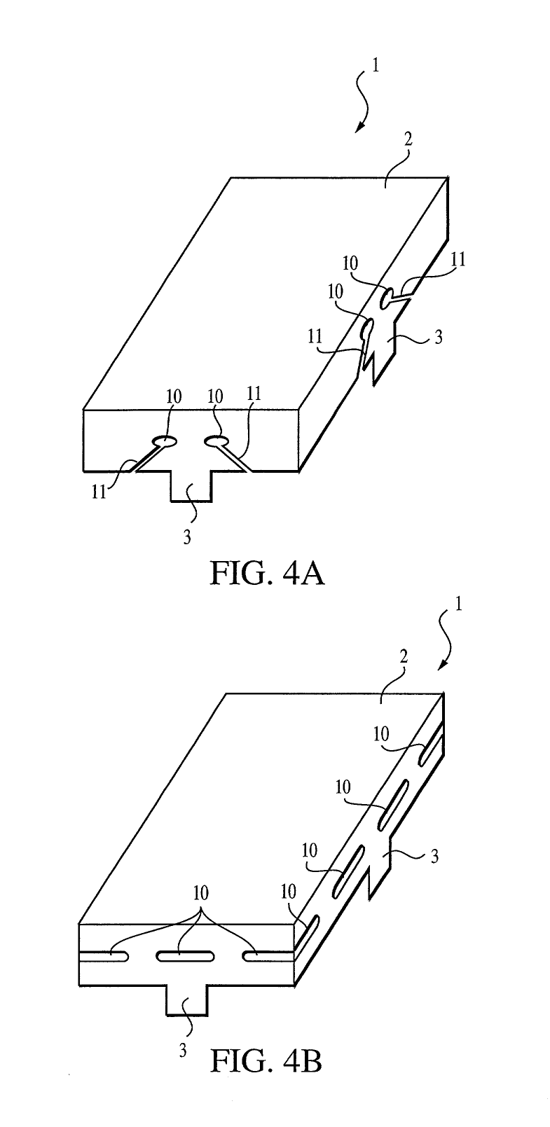

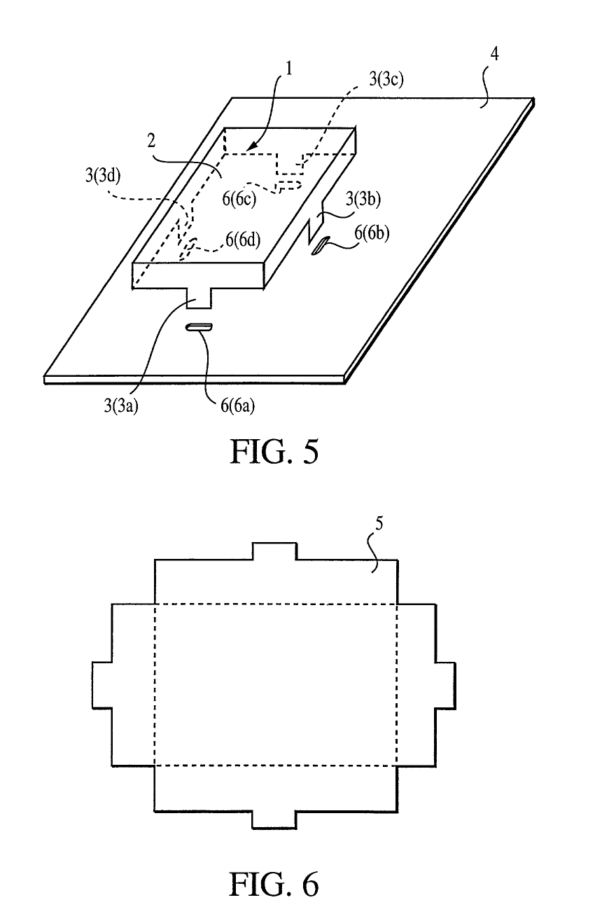

Also, in the first and third embodiments, the direction in which the cutout 11 is formed is parallel to the direction in which the leg sections 3 protrude. However, as shown in FIG. 4A, the direction of the cutout 11 need not be parallel to the direction in which the leg sections 3 protrude.

Also, the shape of the insertion openings 10 is not restricted to the shapes shown in FIGS. 2 and 3. The shape may be varied in any shape as long as it allows insertion of a cutting tool and is effective in preventing the reduction in the electromagnetic-shielding effect.

Also, in the third embodiment, the cutting lines 13 are drawn so as to quarter the cover section 2. However, the cutting lines 13 may be drawn in different ways as required. Also, positions of the insertion openings 10 may be different as required. For example, the insertion openings 10 may be positioned as shown in FIG. 4B. Furthermore, although the insertion openings 10 are formed on the top portion 2a of the cover section 2, they may be formed on peripheral side faces of the cover section 2, as shown in FIG. 4B.

What is claimed is:

1. A shielding case for serving as an electromagnetic shield, comprising:
a cover section for covering electronic components mounted on a substrate;
a plurality of leg sections for attaching, each of which protrudes from said cover section toward said substrate and is inserted in through-holes provided on said substrate; and
a plurality of tool-insertion openings provided on said cover section for use in cutting each of said leg sections away from said cover section.

2. A shielding case according to claim 1, further comprising a plurality of cutouts on said cover section, each of which is extended from an edge of an opening on the substrate-side to each of said tool-insertion openings.

3. A shielding case for serving as an electromagnetic shield, comprising:
a cover section for covering electronic components mounted on a substrate;
a plurality of leg sections for attaching, each of which protrudes from said cover section toward said substrate and is inserted in through-holes provided on said substrate; and
a plurality of tool-insertion openings which is provided serially on the cover section along cutting lines for separating said leg sections to which the plurality of tool-insertion openings correspond via tool-cutting portions, thereby allowing said cover section to be separated for each of said leg sections.

4. A shielding case according to one of claims 1 and 3, wherein said cover section is defined as a box-like shape in which said cover section having an opening at the substrate side, and said tool-insertion openings are formed on the top portion of the cover section, which opposes said substrate.

5. An electronic device comprising at least one of the shielding cases according to one of claims 1 to 4.
